(19) United States
(12) Patent Application Publication
(10) Pub. No.: US 2012/0200816 A1
(43) Pub. Date: Aug. 9, 2012

(54) ELECTRONIC DEVICES HAVING REDUCED SUSCEPTIBILITY TO NEWTON RINGS, AND/OR METHODS OF MAKING THE SAME

(75) Inventors: Alexey KRASNOV, Canton, MI (US); Willem den Boer, Brighton, MI (US); David M. Broadway, Northville, MI (US)

(73) Assignee: Guardian Industries Corp., Auburn Hills, MI (US)

(21) Appl. No.: 13/020,987

(22) Filed: Feb. 4, 2011

(51) Int. Cl. G02F 1/1335; H05K 13/00; B05D 5/00; G02B 1/11; B05D 5/06

(52) U.S. Cl. 349/137; 359/601; 427/162; 427/165; 427/108

(57) ABSTRACT

Certain example embodiments relate to electronic devices (e.g., LCD or other display devices) having reduced susceptibility to Newton Rings, and/or methods of making the same. In certain example embodiments, the electronic device includes at least first and second glass substrates. An Anti-Newton Ring (ANR)/antireflective (AR) coating is provided on the second and/or third surface of the electronic device (e.g., on an inner surface of the cover glass and/or on an outer surface of the color filter substrate of an LCD device) so as to help reduce the formation of Newton Rings caused by the air pockets that surround one or more points of unintentional glass deformation. This may be made possible in certain example embodiments because the ANR coating is optically matched to reduce reflections of light between the first and second substrates.

### FIELD OF THE INVENTION

Certain example embodiments of this invention relate to electronic devices, and/or methods of making the same. More particularly, certain example embodiments of this invention relate to improved display devices (e.g., LCD devices) having reduced susceptibility to Newton Rings, and/or methods of making the same. In certain example embodiments, an antireflective (AR) coating is provided on cover glass of the display device so as to help reduce the formation of Newton Rings caused by the air pockets that surround one or more points of unintentional glass deformation.

### BACKGROUND AND SUMMARY OF EXAMPLE EMBODIMENTS OF THE INVENTION

LCD devices are known in the art. See, for example, U.S. Pat. Nos. 7,602,360; 7,408,606; 6,356,335; 6,016,178; and 5,598,285, each of which is hereby incorporated herein in its entirety.

FIG. 1 is a cross-sectional view of a typical LCD display device 1. The display device 1 generally includes a layer of liquid crystal material 2 sandwiched between first and second substrates 4 and 6, and the first and second substrates 4 and 6 typically are borosilicate glass substrates. The first substrate 4 often is referred to as the color filter substrate, and the second substrate 6 often is referred to as the active or TFT substrate.

The first or color filter substrate 4 typically has a black matrix 8 formed thereon, e.g., for enhancing the color quality of the display. To form the black matrix, a polymer, acrylic, polyimide, metal, or other suitable base may be disposed as a blanket layer and subsequently patterned using photolithography or the like. Individual color filters 10 are disposed in the holes formed in the black matrix. Typically, the individual color filters often comprise red 10a, green 10b, and blue 10c color filters, although other colors may be used in place of or in addition to such elements. The individual color filters may be formed photolithographically, by inkjet technology, or by other suitable technique. A common electrode 12, typically formed from indium tin oxide (ITO) or other suitable conductive material, is formed across substantially the entirety of the substrate or over the black matrix 12 and the individual color filters 10a, 10b, and 10c.

The second or TFT substrate 6 has an array of TFTs 14 formed thereon. These TFTs are selectively actuatable by drive electronics (not shown) to control the functioning of the liquid crystal light valves in the layer of liquid crystal material 2. TFT substrates and the TFT arrays formed thereon are described, for example, in U.S. Pat. Nos. 7,589,799; 7,071,036; 6,884,569; 6,580,093; 6,362,028; 5,926,702; and 5,838,037, each of which is hereby incorporated herein in its entirety.

Although not shown in FIG. 1, a light source, one or more polarizers, alignment layers, and/or the like may be included in a typical LCD display device. Cover glass also may be provided, e.g., to help protect the color filter substrate and/or other more internal components.

In many optical assemblies including, for example, flat-panel displays like LCDs, photographic enlargers, touch-panel displays, photocopiers, etc., Newton Rings are formed. The Newton Ring phenomenon is observed, for example, when two pieces of glass (or other at least partially transparent media, such as transparent conducting oxide (TCO) coated glass in the case of touch-panel displays) are brought into close proximity to each other and form an air pocket.

FIG. 2 is a partial schematic view that helps explain the appearance of Newton Rings. More particularly, first and second substrates 20 and 22 are provided in spaced apart relation to one another. However, the first and second substrates 20 and 22 are not perfectly parallel to one another. The lack of a parallel relation may be caused, for example, by flawed mating techniques as between the first and second substrates 20 and 22, bending of one or both substrates, etc. The lack of a parallel relation creates air pockets 24a and 24b. Some light 26a is able to travel through the first and second substrates 20 and 22.

However, some transmitted or/and reflected light 26b bounces between facing “inner” surfaces of the first and second substrates 20 and 20. The bouncing light 26b constructively interferes with beams passing through the glass that is not reflected. The resultant interference pattern creates the unwanted Newton Rings 28. Newton Rings, when viewed with monochromatic light, appear as a series of concentric, alternating bright and dark rings centered at the point of contact between the two surfaces. When viewed with white light, Newton Rings appear as a concentric ring pattern of rainbow colors because the different wavelengths of light interfere at different thicknesses of the air pocket between the surfaces. Newton Rings generally can be made to appear by pressing in on the outermost surface of an LCD device.

Newton Rings are undesirable in most applications because they typically are seen to degrade the image quality, producing a negative aesthetic affect.

A number of techniques have emerged in an attempt to reduce the occurrence of Newton Rings. See, for example, U.S. Pat. Nos. 7,342,253; 6,956,631; 6,953,432; 6,429,921; and 5,594,574, as well as U.S. Publication Nos. 2002/0154100; 2008/0024870; and 2010/0165551. The entire contents of each of these patents/published applications are hereby incorporated herein by reference.

Many currently available practical Anti-Newton Ring (ANR) solutions in photographic enlargers, for example, are primarily based on the physical separation of two pieces of glass (or glass and the film) by creating microscopic roughness of one of the glass surfaces. This roughness typically is created by mild chemical texturing of the glass or by embedding particles of a suitable size in a polymer resin coating on the glass. There are a number of variations of these solutions.

FIG. 3 is a partial schematic view of an illustrative LCD device having a structure that causes Newton Rings to appear. As shown in FIG. 3, a layer comprising liquid crystal material is sandwiched by a color filter substrate 4 and a TFT substrate 6. Cover glass 32 is provided as an outermost protective layer. The cover glass has a point of unintentional glass deformation 34 which, as indicated above, creates air pockets 24a and 24b. Constructive interference of light from the backlight 36 passing through the rear polarizer 38a, the TFT substrate 6, the layer comprising liquid crystal material 2, the color filter substrate 4, and the front polarizer 38b proximate to the point of unintentional glass deformation 34 and the air pockets 24a and 24b causes the appearance of Newton Rings 28.

In certain LCD designs, thin cover glass is laminated to the front polarizer. The lamination of the thin cover glass to the front polarizer, however, creates additional unwanted light reflection because of the difference in the refractive indexes between the lamination material and the glass. In addition, the lamination process sometimes may adversely affect the production yield, as the entire unit may be lost if, at the final production stage, the lamination of the cover glass to the display goes wrong.

In certain designs, the cover glass is not laminated to the front polarizer and is simply placed against it. In this case, some points of the cover glass may touch the front polarizer or may be provided in close proximity to it, creating Newton Rings.

Unfortunately, however, conventional ANR techniques generally are not suitable for LCD and/or other flat panel display products. For example, creating a textured surface and/or the incorporating of embedded particles typically produces haze. This haze, in turn, typically is undesirable in display applications, because the haze leads to image distortion that often is found unacceptable.

Thus, it will be appreciated that there is a need in the art for improved Anti-Newton Ring techniques. More particularly, it will be appreciated that there is a need in the art for methods of making flat-panel display (e.g., LCD) devices that have a reduced susceptibility to the formation of Newton Rings, and/or devices made by such methods.

Certain example embodiments of this invention relate to a liquid crystal display (LCD) device. A TFT substrate and a color filter substrate sandwich a layer comprising liquid crystal material. A backlight is configured to emit light and is provided adjacent to the TFT substrate. A cover glass substrate is adjacent to the color filter substrate. At least one air pocket is formed in an area between the color filter substrate and the cover glass substrate and is proximate to a corresponding deformation location in or on the cover glass substrate. A first antireflective (AR) coating is provided, directly or indirectly, on either (a) a first major surface of the cover glass substrate facing the color filter substrate or (b) a major surface of the color filter substrate facing the cover glass substrate. The first AR coating is optically tuned to reduce constructive interference of light emitted from the backlight in areas proximate to the at least one air pocket and the corresponding deformation location, and between facing surfaces of the color filter substrate and the cover glass substrate, in order to correspondingly reduce the occurrence and/or intensity of Newton Rings.

Certain example embodiments of this invention relate to an electronic device. First and second glass substrates are substantially parallel to one another. A backlight is configured to emit light. At least one deformation location is formed in the first glass substrate, with each said deformation location being at least partially surrounded by corresponding air pockets, and with the first and second glass substrates being non-parallel to one another in areas proximate to the at least one deformation location and corresponding air pockets. An Anti-Newton Ring (ANR) coating is provided on a major surface of the first glass substrate facing the second substrate. The ANR coating is adapted to reduce reflections of light, emitted from the backlight, between the first and second substrates to correspondingly reduce the occurrence and/or intensity of Newton Rings.

Certain example embodiments of this invention relate to a method of making a coated article. An Anti-Newton Ring (ANR) coating is disposed on a major surface of a first glass substrate. The first glass substrate is orientable or positionable in substantially parallel relation to a second glass substrate such that the ANR coating faces the second glass substrate. At least one deformation location is formed in the first glass substrate, with each said deformation location being at least partially surrounded by corresponding air pockets, and with the first and second glass substrates being non-parallel to one another in areas proximate to the at least one deformation location and corresponding air pockets. The ANR coating is adapted to reduce reflections of light, emitted from a backlight, between the first and second substrates to correspondingly reduce the occurrence and/or intensity of Newton Rings.

Certain example embodiments of this invention relate to a method of making an electronic device. First and second glass substrates are provided in substantially parallel relation to one another. At least one deformation location is formed in the first glass substrate, with each said deformation location being at least partially surrounded by corresponding air pockets, and with the first and second glass substrates being non-parallel to one another in areas proximate to the at least one deformation location and corresponding air pockets. An Anti-Newton Ring (ANR) coating is disposed on a major surface of the first glass substrate facing the second substrate. The ANR coating is adapted to reduce reflections of light, emitted from a backlight disposed adjacent to the second substrate, between the first and second substrates to correspondingly reduce the occurrence and/or intensity of Newton Rings.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a cross-sectional view of a typical LCD display device;

FIG. 2 is a partial schematic view that helps explain the appearance of Newton Rings;

FIG. 3 is a partial schematic view of an illustrative LCD device having a structure that causes Newton Rings to appear;

FIG. 4 is a partial schematic view of an improved LCD device having a structure that helps reduce the incidence of Newton Rings in accordance with an example embodiment;

FIG. 5 is a coated article including an example antireflective/Anti-Newton Ring coating in accordance with an example embodiment;

FIGS. 6a-6d are graphs simulating plots of transmission (%) vs. wavelength (nm) for 400 nm, 800 nm, 2000 nm, and 4000 nm air gaps, with and without there-layer AR coatings on the inner (second) surface of the cover glass substrate;

FIGS. 7a-7b is a three-dimensional map of the interference pattern from the glass samples without and with an AR coating, respectively; and

FIGS. 8a-8b demonstrate the calculated integrated photopic transmission (normalized to the sensitivity of the human eye) of the LCD light through two pieces of glass stack against each other with a thin air gap without and with an AR coating, respectively.

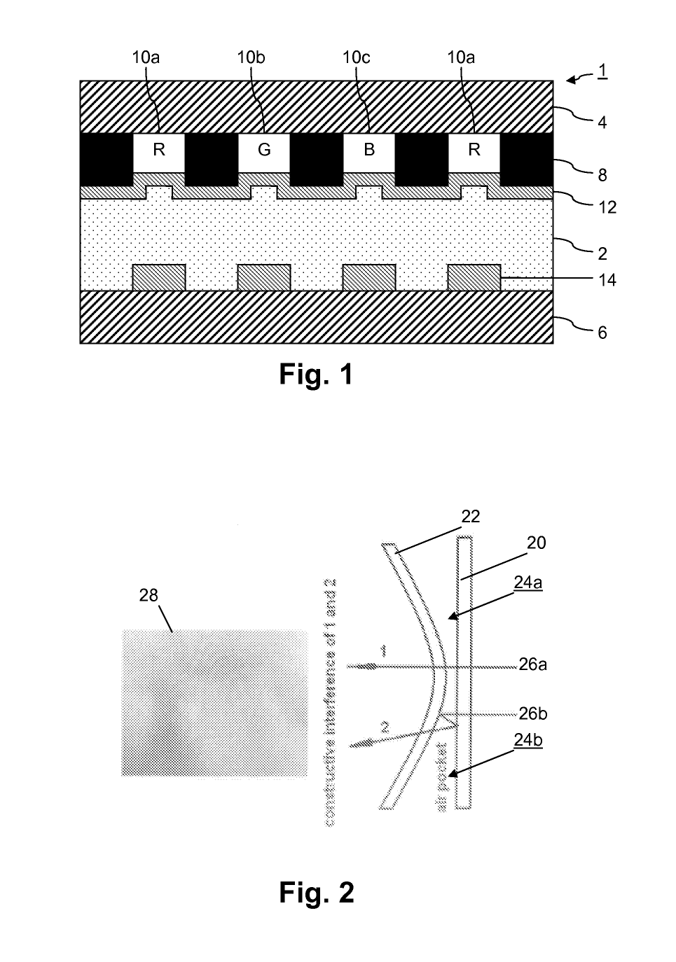

### DETAILED DESCRIPTION OF EXAMPLE EMBODIMENTS OF THE INVENTION

Certain example embodiments relate to methods of making flat-panel display (e.g., LCD) devices that have a reduced susceptibility to the formation of Newton Rings, and/or devices made by such methods. In certain example embodiments, an antireflective (AR) coating is provided on cover glass of the display device so as to help reduce the formation of Newton Rings caused by the air pockets that surround one or more points of unintentional glass deformation. In certain example embodiments, constructive optical interference responsible for the appearance of Newton Rings is reduced, e.g., by reducing reflection of at least one internal glass surface (of the cover glass or the front polarizer). Certain example embodiments therefore may not eliminate the close contact of the two pieces of glass, but may instead reduce the optical sensitivity of the entire assembly to such a contact.

In certain example embodiments, the second surface of the cover LCD glass is coated in such a way as to help reduce the formation of a coherent optical wave that constructively interferes with the transmitted light. In certain example embodiments, an antireflective (AR) coating may be provided on the second surface of the cover glass that faces the front polarizer. From an optical perspective, this design advantageously reduces light reflection, has ANR properties, and improves the scratch sensitivity of the AR coating by placing it inside the display.

In certain example embodiments, an AR coating may be placed on one or both major surfaces of the cover glass. In example embodiments where an AR coating is provided to both major surfaces of the cover glass, it is possible to further reduce light reflection while also serving an ANR role.

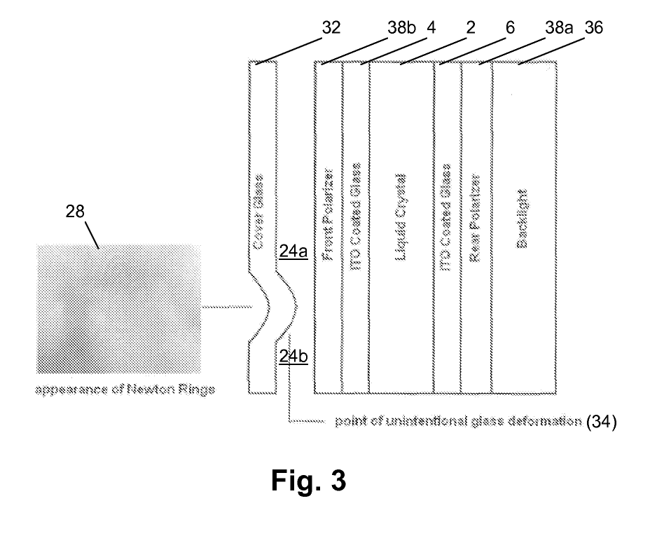

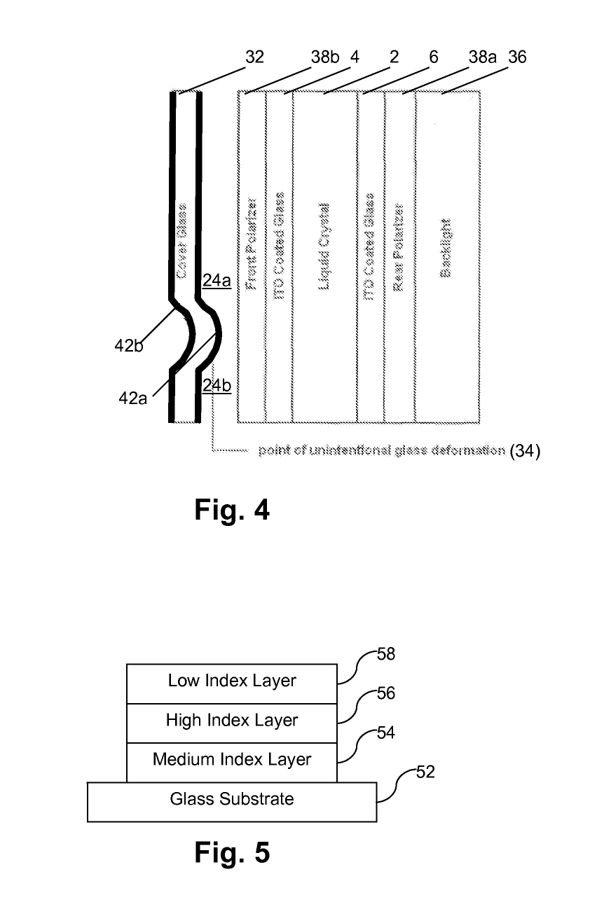

FIG. 4 is a partial schematic view of an improved LCD device having a structure that helps reduce the incidence of Newton Rings in accordance with an example embodiment. FIG. 4 is like FIG. 3, except that first and second AR coatings 42a and 42b are provided to the cover glass substrate 32. Even though there is a point of glass deformation 34 that has surrounding air pockets 24a and 24b, light from the backlight 36 has a reduced reflection at both major surfaces of the cover glass substrate 32 because of the presence of the first and second AR coatings 42a and 42b. Because internal reflection is reduced, there is a corresponding reduction in constructive interference in areas proximate the point of glass deformation 34 and/or the air pockets 24a and 24b. The reduction of constructive interference, in turn, reduces the likelihood of Newton Rings forming.

Any AR coating may be used in connection with different embodiments of this invention. The AR coating may be sputter deposited, wet applied, etc. In certain example embodiments, an AR film (e.g., an adhesive AR film) may be used. In certain example embodiments, the AR layer is a thin-film stack comprising three layers. The layers may have different thicknesses and/or refractive indexes. For instance, the middle index may have a higher refractive index compared to the surrounding layers. A medium/high/low index stack may be provided in certain example embodiments. Additional layers may that generally alternate between high and low indexes also may be provided. Materials that may be used in connection with the high index layer may include, for example, TiNbOx, TiOx, NbOx, NbZrOx, TiCrOx, etc. Examples of the lower-index layers include, for instance, SiOx, SiOxNy, SiTiOx, AlOxNy, etc. Layer thicknesses and optical indexes advantageously may be tuned in such a way as to help suppress constructive optical interference of the transmitted light.

As an example, the following physical thicknesses and refractive indexes (at 550 nm) may be provided:

| | Thickness | Example | Refractive |
|---|---|---|---|
| Layer | Range | Thickness | Index |
| Medium Index | 75-140 nm | 90-120 nm | 1.6-1.9 |
| (Adjacent Cover Glass) | | | |
| High Index | 5-30 nm | 10-25 nm | 2.2-2.6 |
| (“Central” Layer) | | | |
| Low Index | 65-140 nm | 80-120 nm | 1.45-1.55 |
| (Closest to Polarizer) | | | |

This arrangement is shown in FIG. 5, which is a coated article including an example antireflective/Anti-Newton Ring coating in accordance with an example embodiment. The FIG. 5 example coated article thus is suitable for use as a cover glass substrate or an outermost substrate in certain example embodiments. In certain example embodiments, the coated side of the article is faces a second substrate. The FIG. 5 example coated article includes a glass substrate 52 directly or indirectly supporting a multi-layer thin film coating comprising, in order moving away from the glass substrate 52, a medium index layer 54, a high index layer 56, and a low index layer 58.

Example three-layer AR coatings also are disclosed in co-pending and commonly assigned application Ser. Nos. 12/923,146 and 12/923,838, the entire contents of which are hereby incorporated herein by reference.

In certain example embodiments, a two-layer AR coating may be provided, wherein the glass substrate supports a coating comprising, in order moving away from the substrate, high and low index layers (e.g., of the above-described or other example thickness and/or refractive indexes). In certain example embodiments, a single layer broadband AR coating may be provided. The index of refraction for the single layer may be, for example, lower than the index of the glass.

As alluded to above, AR coatings with more than three layers also may be provided. For instance, medium/high/low layers with additional high/low alternating layers also may be provided. In certain example embodiments, a stress-reducing layer may be provided between the cover glass and the first medium index layer. Example four-layer AR coatings also are disclosed in co-pending and commonly assigned application Ser. No. 12/______, (filed on Jan. 27, 2011 under atty. dkt. no. 3691-2239 and entitled “HEAT TREATABLE FOUR LAYER ANTI-REFLECTION COATING”).

Also as alluded to above, AR coatings may be provided to both surfaces of the cover glass substrate in different embodiments of this invention. In certain example embodiments, in the alternative or in addition, an AR coating may be provided to a front surface of the front polarizer, such that the AR coating disposed on the front polarizer faces the cover glass. In embodiments where multiple AR coatings are used for Newton Ring suppression, the same or different AR coatings may be used.

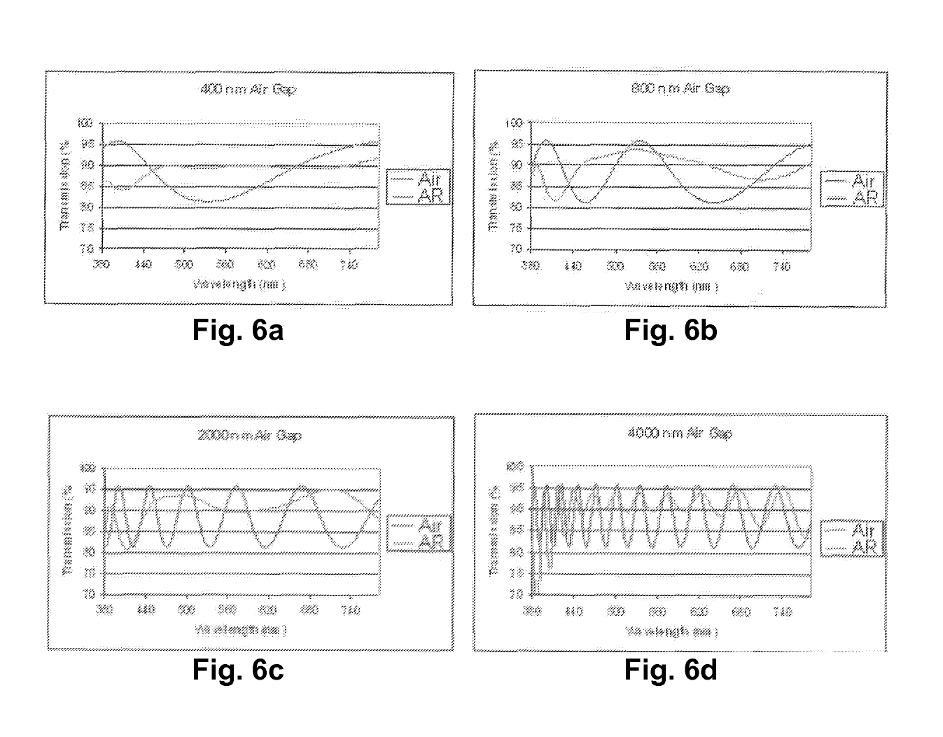

FIGS. 6a-6d are graphs simulating plots of transmission (%) vs. wavelength (nm) for 400 nm, 800 nm, 2000 nm, and 4000 nm air gaps, with and without there-layer AR coatings on the inner (second) surface of the cover glass substrate. Thus, FIGS. 6a-6d simulate the results of the optical transmission spectra through two pieces of glass separated by thin air gaps (of 400 nm, 800 nm, 2000 nm, and 4000 nm, respectively), with and without there-layer AR coatings on the inner (second) surface of the cover glass substrate. The observed reduction between the minima and maxima of the interference fringes clearly indicates the suppression of the optical interference effect and, thus, the reduced formation and/or severity of Newton Rings.

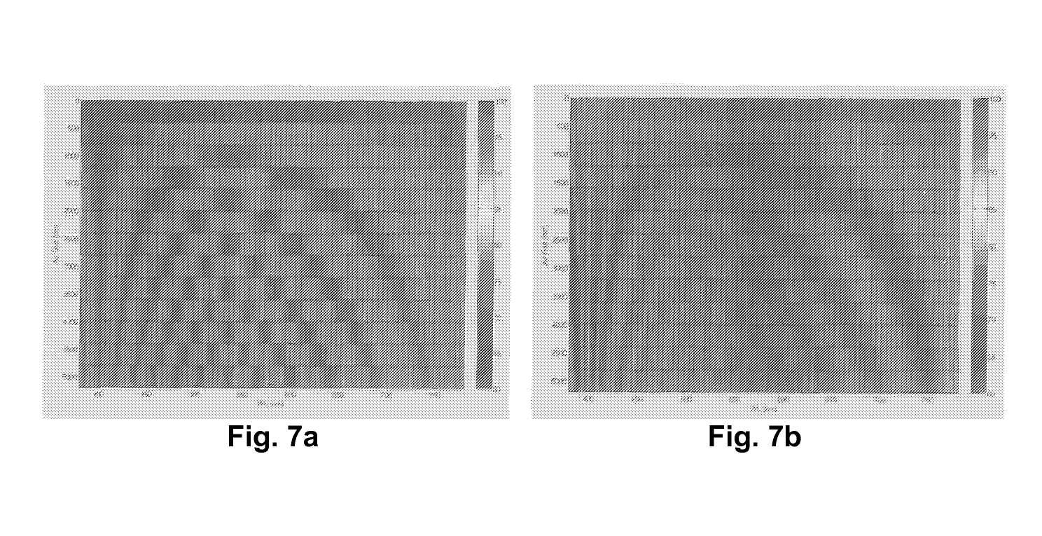

FIGS. 7a-7b is a three-dimensional map of the interference pattern from the glass samples without and with an AR coating, respectively. Pseudo colors represent the intensity of the transmitted light. As is evidenced from FIGS. 7a-7b, the AR coating on the second surface of the cover glass greatly suppresses the formation of the interference pattern.

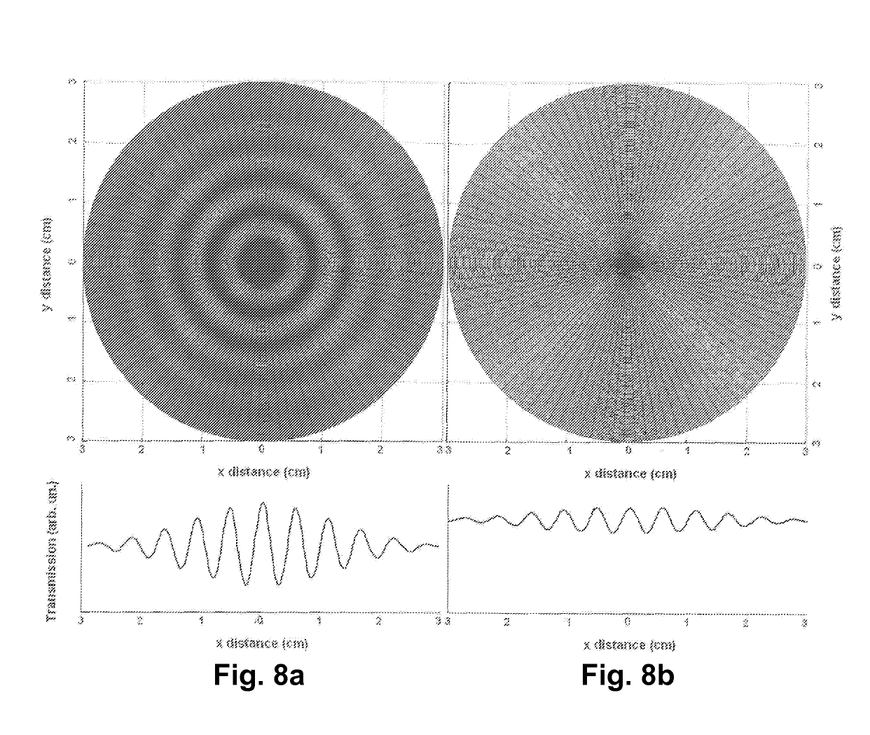

FIGS. 8a-8b demonstrate the calculated integrated photopic transmission (normalized to the sensitivity of the human eye) of the LCD light through two pieces of glass stack against each other with a thin air gap without and with an AR coating, respectively. As can be seen, the presence of the AR layer greatly reduces formation of Newton Rings in a range in which the human eye is sensitive.

Although certain example embodiments have been described as relating to LCD devices, the techniques described herein may be applied to other display devices including, for example, plasma display devices, touch panels, etc. Furthermore, the techniques of certain example embodiments may be applied to other, non-display related applications such as, for example, photographic enlargers, photocopiers, etc. In general, any electronic device in which two substrates are adjacent to one another may have a Newton Ring issue and thus may benefit from the example embodiments disclosed herein, which generally involve disposing an antireflective coating on a surface of adjacent to the air pockets and/or glass deformations that otherwise would lead to Newton Ring formation.

Also, although certain example embodiments have been described in connection with glass substrates, the techniques described herein may apply with respect to substrates made of other materials. Thus, while the cover glass substrates of certain example embodiments may be borosilicate glass, soda lima glass, or other forms of glass, devices including plastic substrates, polymer substrates, and/or materials may benefit from the example techniques described herein.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A liquid crystal display (LCD) device, comprising:
a TFT substrate and a color filter substrate sandwiching a layer comprising liquid crystal material;
a backlight configured to emit light and provided adjacent to the TFT substrate;
a cover glass substrate adjacent to the color filter substrate;
at least one air pocket in an area between the color filter substrate and the cover glass substrate and proximate to a corresponding deformation location in or on the cover glass substrate; and
a first antireflective (AR) coating provided, directly or indirectly, on either (a) a first major surface of the cover glass substrate facing the color filter substrate or (b) a major surface of the color filter substrate facing the cover glass substrate,
wherein the first AR coating is optically tuned to reduce constructive interference of light emitted from the backlight in areas proximate to the at least one air pocket and the corresponding deformation location, and between facing surfaces of the color filter substrate and the cover glass substrate, in order to correspondingly reduce the occurrence and/or intensity of Newton Rings.

2. The LCD device of claim 1, wherein the first AR coating comprises, in order moving away from the substrate on which it is provided:
a first medium index layer;
a first high index layer; and
a first low index layer,
wherein the first medium index layer has a refractive index of 1.6-1.9, the first high index layer has a refractive index greater than 2.0, and the first low index layer has a refractive index less than 1.6.

3. The LCD device of claim 2, wherein the first low index layer has a refractive index of 1.45-1.55.

4. The LCD device of claim 3, wherein the first high index layer has a refractive index of 2.2-2.6.

5. The LCD device of claim 4, wherein:
the first medium index layer comprises an oxide and/or nitride of Si, Ti, and/or Al,
the first high index layer comprises an oxide of Ti, Nb, Zr, and/or Cr, and
the first low index layer comprises an oxide and/or nitride of Si, Ti, and/or Al.

6. The LCD device of claim 1, wherein the first AR coating consists essentially of a single thin film layer having a refractive index lower than a refractive index of the cover glass substrate.

7. The LCD device of claim 1, wherein the first AR coating is an adhesively applied AR film.

8. The LCD device of claim 2, wherein the first AR coating is provided on the first major surface of the cover glass substrate, and
further comprising a second AR coating provided, directly or indirectly, on either a second major surface of the cover glass substrate or the major surface of the color filter substrate facing the cover glass substrate.

9. The LCD device of claim 1, further comprising:
a front polarizer disposed on the color filter substrate; and
a rear polarizer interposed between the TFT substrate and the backlight.

10. An electronic device, comprising:
first and second glass substrates that are substantially parallel to one another;
a backlight configured to emit light;
at least one deformation location in the first glass substrate, each said deformation location being at least partially surrounded by corresponding air pockets, the first and second glass substrates being non-parallel to one another in areas proximate to the at least one deformation location and corresponding air pockets; and
an Anti-Newton Ring (ANR) coating provided on a major surface of the first glass substrate facing the second substrate, the ANR coating being adapted to reduce reflections of light, emitted from the backlight, between the first and second substrates to correspondingly reduce the occurrence and/or intensity of Newton Rings.

11. The electronic device of claim 10, wherein the ANR coating comprises, in order moving away from the first substrate:
a medium index layer comprising an oxide and/or nitride of Si, Ti, and/or Al,
a high index layer comprising an oxide of Ti, Nb, Zr, and/or Cr, and
a low index layer comprising an oxide and/or nitride of Si, Ti, and/or Al.

12. The electronic device of claim 11, wherein the medium index layer has a refractive index of 1.6-1.9, the first high index layer has a refractive index greater than 2.0, and the first low index layer has a refractive index less than 1.6

13. The electronic device of claim 12, wherein the thicknesses of the medium, high, and low index layers are 90-120 nm, 10-25 nm, and 80-120 nm, respectively.

14. The electronic device of claim 10, wherein the electronic device is a flat panel display device or a touch panel device.

15. The electronic device of claim 10, wherein the electronic device is a photocopier or photographic enlarger.

16. The electronic device of claim 10, wherein the first and second substrates are no more than 2000 nm apart in areas proximate to the air pockets.

17. A method of making a coated article, the method comprising:
disposing an Anti-Newton Ring (ANR) coating on a major surface of a first glass substrate, wherein:
the first glass substrate is orientable in substantially parallel relation to a second glass substrate such that the ANR coating faces the second glass substrate,
at least one deformation location is formed in the first glass substrate, each said deformation location being at least partially surrounded by corresponding air pockets, the first and second glass substrates being non-parallel to one another in areas proximate to the at least one deformation location and corresponding air pockets, and
the ANR coating is adapted to reduce reflections of light, emitted from a backlight, between the first and second substrates to correspondingly reduce the occurrence and/or intensity of Newton Rings.

18. The method of claim 17, wherein the ANR coating comprises, in order moving away from the first substrate:
a medium index layer comprising an oxide and/or nitride of Si, Ti, and/or Al,
a high index layer comprising an oxide of Ti, Nb, Zr, and/or Cr, and
a low index layer comprising an oxide and/or nitride of Si, Ti, and/or Al.

19. The method of claim 18, wherein the medium index layer has a refractive index of 1.6-1.9, the first high index layer has a refractive index greater than 2.0, and the first low index layer has a refractive index less than 1.6

20. The method of claim 19, wherein the thicknesses of the medium, high, and low index layers are 90-120 nm, 10-25 nm, and 80-120 nm, respectively.

21. The method of claim 20, wherein the first high index layer has a refractive index of 2.2-2.6.

22. The method of claim 21, wherein the first substrate is a cover glass substrate and the second substrate is a color filter substrate.

23. A method of making an electronic device, the method comprising:
providing first and second glass substrates in substantially parallel relation to one another, wherein:
at least one deformation location is formed in the first glass substrate, each said deformation location being at least partially surrounded by corresponding air pockets, the first and second glass substrates being non-parallel to one another in areas proximate to the at least one deformation location and corresponding air pockets, and
an Anti-Newton Ring (ANR) coating is disposed on a major surface of the first glass substrate facing the second substrate, the ANR coating being adapted to reduce reflections of light, emitted from a backlight disposed adjacent to the second substrate, between the first and second substrates to correspondingly reduce the occurrence and/or intensity of Newton Rings.

24. The method of claim 23, wherein the electronic device is a flat panel display device.

25. The method of claim 23, wherein the ANR coating comprises, in order moving away from the first substrate:
a medium index layer comprising an oxide and/or nitride of Si, Ti, and/or Al, and having a refractive index of 1.6-1.9,
a high index layer comprising an oxide of Ti, Nb, Zr, and/or Cr and having a refractive index of greater than 2.1, and
a low index layer comprising an oxide and/or nitride of Si, Ti, and/or Al and having a refractive index of less than 1.6.
